(19) United States
(12) Patent Application Publication
(10) Pub. No.: US 2026/0011354 A1
(43) Pub. Date: Jan. 8, 2026

(54) MEMORY DEVICE AND METHOD FOR PERFORMING PROGRAM OPERATION OF THE MEMORY DEVICE

(71) Applicant: SK hynix Inc., Gyeonggi-do (KR)

(72) Inventors: Jae Woong KIM, Gyeonggi-do (KR); In Su PARK, Gyeonggi-do (KR); Jung Shik JANG, Gyeonggi-do (KR); Dong Jae JUNG, Gyeonggi-do (KR); Young Hwa JO, Gyeonggi-do (KR); Jung Dal CHOI, Gyeonggi-do (KR)

(21) Appl. No.: 19/221,529

(22) Filed: May 29, 2025

(30) Foreign Application Priority Data
Jul. 3, 2024 (KR) 10-2024-0087594
Dec. 24, 2024 (KR) 10-2024-0194930

(51) Int. Cl. G11C 7/22

(52) U.S. Cl. CPC G11C 7/22

(57) ABSTRACT

A memory device includes a memory cell array, a peripheral circuit, and control logic. The memory cell array includes a plurality of memory cells coupled to a selected word line. The peripheral circuit performs program operations including a plurality of program loops including a program pulse apply operation that applies fixed program pulses having a constant voltage level and a verify operation. The control logic controls the peripheral circuit to perform a first verify operation included in an N-th program loop among the plurality of program loops before performing a first program pulse apply operation included in the N-th program loop and to apply a program inhibition voltage to memory cells determined, among the plurality of memory cells, based on a result of the first verify operation and target threshold voltages of the plurality of memory cells when the first program pulse apply operation is performed.

### CROSS-REFERENCE TO RELATED APPLICATION

The present application claims priority under 35 U.S.C. § 119(a) to Korean patent application number 10-2024-0087594, filed on Jul. 3, 2024 and Korean patent application number 10-2024-0194930, filed on Dec. 24, 2024, the entire disclosures of which are incorporated herein by reference.

### BACKGROUND

### 1. Technical Field

Various embodiments of the present disclosure generally relate to a memory device, and more particularly, to a memory device and a method for performing a program operation that increases threshold voltages of memory cells to a target threshold voltage by applying program pulses having the same magnitude to the memory cells.

### 2. Related Art

A memory device may be classified as a volatile memory device or a non-volatile memory device. A volatile memory device may store data only when power is supplied thereto and may lose stored data when power is not supplied. A non-volatile memory device may retain stored data even when supply of power is interrupted or blocked.

A memory device may perform a program operation by applying a program pulse to memory cells. As the number of threshold voltage distributions of the memory cells increases, it is necessary to improve the threshold voltage distributions of the memory cells to be narrower. Increasing the magnitude of the program pulse as the number of program loops performed increases may cause over-programming, which may result in wider threshold voltage distributions of the memory cells.

### SUMMARY

Various embodiments of the present disclosure are directed to a memory device and a method for performing a program operation that improves a threshold voltage distribution of memory cells by applying a fixed program pulse to the memory cells according to a verify operation on a memory cell performed before an operation of applying a program pulse during the program operation.

According to an embodiment of the present disclosure, a memory device may include a memory cell array, a peripheral circuit, and control logic. The memory cell array may include a plurality of memory cells coupled to a selected word line. The peripheral circuit may perform program operations including a plurality of program loops including a program pulse apply operation that applies fixed program pulses having a constant voltage level to the plurality of memory cells and a verify operation that detects whether a threshold voltage of a memory cell has reached a target level. The control logic may control the peripheral circuit to perform a first verify operation included in an N-th program loop among the plurality of program loops before performing a first program pulse apply operation included in the N-th program loop and to apply a program inhibition voltage to memory cells determined, among the plurality of memory cells, based on a result of the first verify operation and target threshold voltages of the plurality of memory cells when the first program pulse apply operation is performed.

According to an embodiment of the present disclosure, a method of operating a memory device may include performing a first verify operation included in an N-th program loop, among a plurality of program loops including a program pulse apply operation that applies fixed program pulses having a constant voltage level to a plurality of memory cells coupled to a selected word line and a verify operation that detects whether a threshold voltage of a memory cell has reached a target level; determining memory cells to which a program inhibition voltage is to be applied among the plurality of memory cells when a first program pulse apply operation included in the N-th program loop is performed, based on a result of the first verify operation and target threshold voltages of the plurality of memory cells; and performing the first program pulse apply operation by applying the program inhibition voltage according to a result of the determination.

According to an embodiment of the present disclosure, a memory device may include a memory cell array, a peripheral circuit, and control logic. The memory cell array may include a plurality of memory cells coupled to a selected word line. The peripheral circuit may perform a program operation including a program pulse apply operation that applies fixed program pulses having a constant voltage level to the plurality of memory cells and a verify operation that detects whether a threshold voltage of a memory cell has reached a target level. The control logic may control the peripheral circuit to perform the verify operation before applying the fixed program pulses and to apply a program inhibition voltage to memory cells determined, among the plurality of memory cells, based on a result of the verify operation and target threshold voltages of the plurality of memory cells.

### BRIEF DESCRIPTION OF THE DRAWINGS

FIG. 1 is a diagram illustrating a memory device according to an embodiment of the present disclosure;

FIG. 2 is a diagram illustrating incremental program pulses applied to memory cells during a program operation;

FIG. 3 is a diagram illustrating a program operation according to an embodiment of the present disclosure;

FIG. 4 is a diagram illustrating a threshold voltage distribution of memory cells which changes according to program pulses applied to the memory cells;

FIG. 5 is a flowchart illustrating a program operation according to an embodiment of the present disclosure; and

FIG. 6 is a diagram of an example of a data storage system including a memory system according to an embodiment of the present disclosure.

### DETAILED DESCRIPTION

Specific structural and functional features of the embodiments of the present disclosure are disclosed in the context of the following embodiments. However, the embodiments may be configured, arranged, or carried out differently than disclosed herein. Thus, the embodiments are not limited to any particular embodiment nor to any specific details. Also, throughout the specification, reference to “an embodiment,” “another embodiment” or the like is not necessarily to only one embodiment, and different references to any such phrase are not necessarily to the same embodiment. Moreover, the use of an indefinite article (i.e., “a” or “an”) means one or more, unless it is clear that only one is intended. Similarly, terms “comprising,” “including,” “having” and the like, when used herein, do not preclude the existence or addition of one or more other elements in addition to the stated element(s).

It should be understood that the drawings are simplified schematic illustrations of the described devices and may not include well known details for avoiding obscuring the features of the invention.

It should also be noted that features present in one embodiment may be used with one or more features of another embodiment without departing from the scope of the present disclosure.

It is further noted, that in the various drawings, like reference numbers designate like elements.

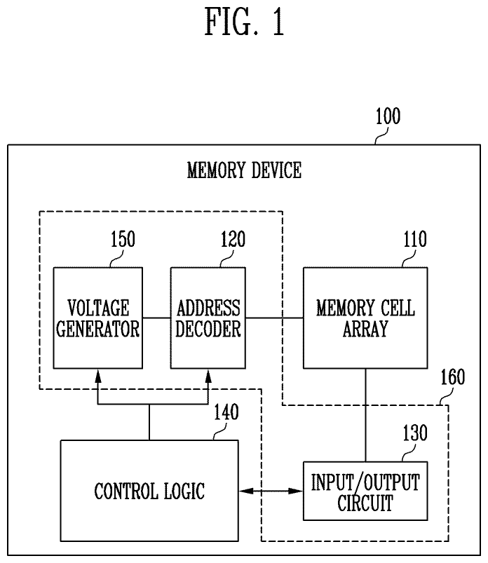

FIG. 1 is a diagram illustrating a memory device 100 according to an embodiment of the present disclosure.

Referring to FIG. 1, the memory device 100 may store data. The memory device 100 may include a memory cell array 110 including memory cells storing data, an address decoder 120 decoding a column address, an input/output circuit 130 transmitting and receiving data to and from an external device of the memory device 100, control logic 140, and a voltage generator 150 generating a plurality of voltages having various voltage levels.

Each of the memory cells included in the memory cell array 110 may be a single-level cell (SLC) storing one bit of data, or may be a memory cell storing multi-bit data. A memory cell storing multi-bit data may be a multi-level cell (MLC) storing two bits of data, a triple-level cell (TLC) storing three bits of data, a quad-level cell (QLC) storing four bits of data, or a penta-level cell (PLC) storing five bits of data, depending on the number of bits in the multi-bit data.

The address decoder 120 may be coupled to the memory cell array 110 via word lines. The address decoder 120 may select a word line by decoding an address received from the input/output circuit 130. The address decoder 120 may apply a voltage received from the voltage generator 150 to the selected word line. The address decoder 120 may operate in response to a control signal received from the control logic 140.

The input/output circuit 130 may include page buffers reading data stored in the memory cells and temporarily store the read data. The input/output circuit 130 may output data stored in the page buffers to an external device of the memory device 100, or may store data received from the external device in the page buffers and store the data in the memory cells.

The page buffers may be coupled to the memory cells via bit lines and may store sensing data which is acquired by sensing threshold voltages of the memory cells during a read operation or a program operation. The sensing data may be transmitted to the control logic 140.

The control logic 140 may control general operations of the memory device 100. The control logic 140 may generate control signals that control the address decoder 120, the input/output circuit 130, and the voltage generator 150 to perform a read operation, a program operation, and an erase operation on the memory cell array 110.

The control logic 140 may determine whether the program operation or a verify operation has failed or passed based on the sensing data received from the input/output circuit 130. Specifically, the control logic 140 may determine the result of the verify operation as a verify-pass when a threshold voltage of a memory cell is higher than a verify voltage. The control logic 140 may determine the result of the program operation as a program-pass when the number of verify-passed memory cells is greater than or equal to a reference value.

The voltage generator 150 may generate voltages used to perform operations of the memory device 100. The voltage generator 150 may include voltage regulators generating voltages having various potentials. The voltage generator 150 may generate a program voltage, a verify voltage, and a read voltage required by the memory device 100. The voltages generated by the voltage generator 150 may be supplied to the memory cells included in the memory cell array 110 via the address decoder 120.

In an embodiment of the present disclosure, the address decoder 120, the input/output circuit 130, and the voltage generator 150 may be referred to as a peripheral circuit 160. The control logic 140 may control the peripheral circuit 160 to perform operations on the memory cells included in the memory cell array 110.

In an embodiment of the present disclosure, the control logic 140 may control the peripheral circuit 160 to perform a program operation on the memory cells. The peripheral circuit 160 may perform a program pulse apply operation for applying a program pulse to the memory cells and a verify operation for detecting whether the threshold voltages of the memory cells have reached a target threshold voltage distribution.

The control logic 140 may group memory cells having the same target threshold voltage together. The control logic 140 may control the peripheral circuit 160 to apply fixed program pulses of constant magnitude to the memory cells having the same target threshold voltage.

The control logic 140 may perform a verify operation on the memory cells before applying a fixed program pulse to the memory cells. The control logic 140 may control the peripheral circuit 160 to apply a program inhibition voltage to memory cells with a threshold voltage higher than the target threshold voltage based on the result of the verify operation.

The verify operation performed before the fixed program pulse is applied may be performed on all memory cells on which the program operation is to be performed. All memory cells on which the program operation is to be performed include memory cells that have already verify-passed and memory cells that have not yet verify-passed.

According to an embodiment of the present disclosure, because the program pulses applied to the memory cells are of the same magnitude, threshold voltage increase of the memory cells is not increased in a stepwise manner, and therefore the narrow threshold voltage distribution of the memory cells may be maintained. Furthermore, even when it is determined that a memory cell having a threshold voltage lower than the target threshold voltage has verify-passed due to a sensing error, the program voltage may be normally applied in a next program loop, thereby maintaining a narrow threshold voltage distribution of the memory cells.

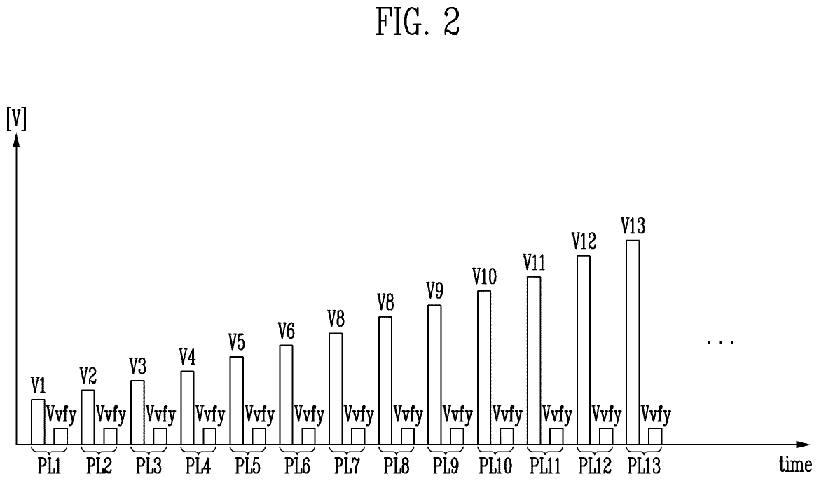

FIG. 2 is a diagram illustrating incremental program pulses applied to memory cells during a program operation.

Referring to FIG. 2, program pulses and verify voltages Vvfy may be applied to the memory cells when a program loop is performed. As the number of program loops that have performed increases, the magnitude of the program pulses applied to the memory cells may be increased in a stepwise manner. In FIG. 2, the horizontal axis represents time and the vertical axis represents the magnitude of the pulse.

By way of example, in FIG. 2, the memory cells to which the program pulses are applied are SLCs and it is illustrated that levels of the verify voltages Vvfy used for the verify operation are the same. However, the embodiment illustrated in FIG. 2 is merely provided as an example, and the verify voltages Vvfy may have a plurality of levels different from each other. For example, when the memory cell is a memory cell storing multi-bit data, such as an MLC, TLC, PLC, or QLC rather than an SLC, a plurality of verify voltages may be applied to the memory cell in response to the application of one program pulse, and the levels of the plurality of verify voltages may be different.

The program operation of a memory cell may include a plurality of program loops. Each of the plurality of program loops may include one program pulse apply operation and one verify operation. For example, a first program loop PL1 includes an operation of applying a first program pulse V1 and an operation of applying the verify voltage Vvfy. Similarly, each of second to thirteenth program loops PL2 to PL13 includes one program pulse apply operation and one verify operation.

The peripheral circuit 160 may perform the first program loop PL1 by applying the first program pulse V1 and the verify voltage Vvfy to the memory cells. After performing the first program loop PL1, the peripheral circuit 160 may perform the second program loop PL2 by applying a second program pulse V2 and the verify voltage Vvfy. The second program pulse V2 may be a voltage that is increased by a step voltage from the first program pulse V1. The magnitude of the step voltage may be predetermined. As the number of program loops performed increases, the magnitude of the program pulses that are applied to the memory cells may be increased in a stepwise manner.

By way of example, FIG. 2 illustrates that the number of program loops performed is 13, but the embodiments are not limited thereto, and the number of program loops performed during a program operation may vary.

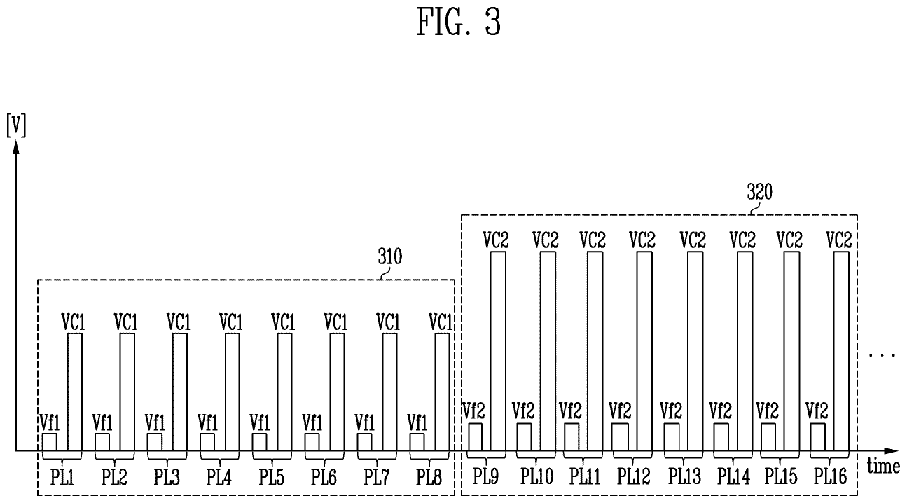

FIG. 3 is a diagram illustrating a program operation according to an embodiment of the present disclosure.

Referring to FIG. 3, a program operation may be performed on memory cells having the same target threshold voltage among a plurality of memory cells coupled to a selected word line. Among descriptions with reference to FIG. 3, descriptions already provided with reference to FIG. 2 above will be omitted for the sake of brevity. FIG. 3 illustrates a first program operation 310 on first memory cells having a target threshold voltage of a first level and a second program operation 320 on second memory cells having a target threshold voltage of a second level. By way of example, the number of program pulses applied to the memory cells having the same target threshold voltage is illustrated as eight.

The peripheral circuit 160 may perform the first program operation 310 by performing the first to eighth program loops PL1 to PL8. When the first program operation 310 is performed, a first fixed program pulse VC1 having a constant voltage level may be applied to the first memory cells.

When the first program loop PL1 is performed, a first verify operation may be performed on all first memory cells. The peripheral circuit 160 may perform the first verify operation by applying a first verify voltage Vf1 to the first memory cells via the selected word line. The result of the first verify operation may be stored in latch circuits included in the page buffers. Data stored in the latch circuits may indicate verify-passed memory cells or verify-failed memory cells among the plurality of memory cells. The page buffers are included in the input/output circuit 130. The control logic 140 may determine, based on the result of the first verify operation, first target memory cells having a threshold voltage lower than the first level among the first memory cells. Although the first verify operation is the initial verify operation of the first program operation 310, verification of an erase state of the memory cells may be required.

When a first program pulse apply operation of applying the first fixed program pulse VC1 to the plurality of memory cells coupled to the selected word line is performed, the control logic 140 may determine, via bit lines, memory cells to which the program inhibition voltage is to be applied. The control logic 140 may determine, as the memory cells to which the program inhibition voltage is to be applied, memory cells having a target threshold voltage not at the first level and memory cells having a threshold voltage at or above the first level among the first memory cells.

In another embodiment of the present disclosure, the control logic 140 may exclude memory cells having a target threshold voltage higher than the first level from the memory cells to which the program inhibition voltage is to be applied. When the memory cells having the target threshold voltage higher than the first level are excluded from the memory cells to which the program inhibition voltage is to be applied, the time required for a program operation on all memory cells may be reduced.

The control logic 140 may determine, as the memory cells to which the program inhibition voltage is to be applied, memory cells other than the first target memory cells among the plurality of memory cells coupled to the selected word line. The control logic 140 may determine a voltage level of the first fixed program pulse VC1 to be applied to the first memory cells based on the first level.

The control logic 140 may control the peripheral circuit 160 to apply the first fixed program pulse VC1 to the plurality of memory cells coupled to the selected word line. The control logic 140 may control the peripheral circuit 160 to apply the program inhibition voltage to the memory cells other than the first memory cells among the plurality of memory cells coupled to the selected word line when the first program pulse apply operation is performed.

After the first program loop PL1 is performed, the second program loop PL2 may be performed. During the second program loop PL2, a second verify operation may be performed on all first memory cells. The control logic 140 may reset the latch circuits storing a first verification result prior to performing the second verify operation. Because the latch circuits are reset, the second verify operation may be performed on all first memory cells, and the second verify operation may be performed independently of the result of the first verify operation. For example, memory cells having the threshold voltage higher than the first level according to the result of the first verify operation may also be subject to the second verify operation. Memory cells that are subject to the second verify operation include both memory cells that have verify-passed in the first verify operation and memory cells that have not verify-passed in the first verify operation. In an embodiment of the present disclosure, the result of the second verify operation may be different from the result of the first verify operation.

Based on the result of the second verify operation, the control logic 140 may determine new first target memory cells having a threshold voltage lower than the first level among the first memory cells. The first target memory cells determined based on the second verify operation may be different from the first target memory cells determined based on the first verify operation.

For example, memory cells of which a threshold voltage is increased to or above the first level by performing the first program pulse apply operation are not included in the first target memory cells. Even memory cells, of which a threshold voltage is lower than the first level but to which the program inhibition voltage is applied due to a sensing error during the first verify operation, may also be included in the first target memory cells because the second verify operation is performed independently of the result of the first verify operation.

The control logic 140 may determine, as the memory cells to which the program inhibition voltage is to be applied, the memory cells other than the first target memory cells among the plurality of memory cells coupled to the selected word line. The control logic 140 may control the peripheral circuit 160 to perform a second program pulse apply operation of applying the first fixed program pulse VC1 to the plurality of memory cells coupled to the selected word line. The control logic 140 may control the peripheral circuit 160 such that, when the second program pulse apply operation is performed, the program inhibition voltage is applied to the memory cells other than the first target memory cells among the plurality of memory cells coupled to the selected word line.

Similarly to the first program loop PL1 and the second program loop PL2, the third to eighth program loops PL3 to PL8 may be performed. Because the latch circuits that store the verification results of the previous program loop are reset, a verify operation on all memory cells coupled to the selected word line is performed anew on each program loop before applying the fixed program pulse. The control logic 140 may determine memory cells to which the program inhibition voltage is to be applied independently of the results of the verify operations performed in the previous program loop. The control logic 140 may control the peripheral circuit 160 to apply the first fixed program pulse VC1 to the plurality of memory cells coupled to the selected word line.

The control logic 140 may determine whether the number of times the first fixed program pulse VC1 is applied has reached a reference value. By way of example, the reference value is 8 in FIG. 3. When the number of times the first fixed program pulse VC1 is applied reaches the reference value, the control logic 140 may determine whether the first program operation 310 has failed.

The control logic 140 may count, after performing the eighth program pulse apply operation included in the eighth program loop PL8, the number of memory cells having a threshold voltage greater than or equal to the first level among the first memory cells. The control logic 140 may determine whether the first program operation 310 has failed based on the number of memory cells having a threshold voltage greater than or equal to the first level. For example, the first program operation may be determined to be a fail when the number of memory cells having the threshold voltage higher than the first level is less than a predetermined fail reference value.

In response to the first program operation 310 being determined to be a pass, the second program operation 320 may be performed during the ninth to sixteenth program loops PL9 to PL16. The second program operation 320 may be performed similarly to the first program operation 310.

A ninth verify operation included in the ninth program loop PL9 is performed before a ninth program pulse apply operation included in the ninth program loop PL9. Voltage level of a second fixed program pulse VC2 and a second verify voltage Vf2 that are applied to the memory cells during the ninth to sixteenth program loops PL9 to PL16 may be determined based on the second level.

Based on the result of the ninth verify operation, the control logic 140 may determine second target memory cells having a threshold voltage lower than the second level among the second memory cells. The result of the ninth verify operation may be stored in the latch circuits included in the page buffers. The control logic 140 may determine, as the memory cells to which the program inhibition voltage is to be applied, memory cells other than the second target memory cells among the plurality of memory cells coupled to the selected word line.

The control logic 140 may control the peripheral circuit 160 to perform the ninth program pulse apply operation of applying the second fixed program pulse VC2 to the memory cells, and to apply the program inhibition voltage to the memory cells other than the second target memory cells among the plurality of memory cells coupled to the selected word line when the ninth program pulse apply operation is performed.

After the ninth program loop PL9 is performed, the tenth program loop PL10 may be performed. Before performing a tenth verify operation included in the tenth program loop PL10, the latch circuits storing the result of the ninth verify operation may be reset. Because the tenth verify operation is performed independently of the result of the ninth verify operation, the second target memory cells determined based on the result of the tenth verify operation may be different from the second target memory cells determined based on the result of the ninth verify operation.

After the ninth to sixteenth program loops PL9 to PL16 are performed, whether the second program operation 320 has failed may be determined. Although only the first program operation 310 and the second program operation 320 are shown in FIG. 3, embodiments of the present disclosure are not limited thereto. For example, when one memory cell is an MLC storing two bits of data, the first to fourth program operations may be performed, and when one memory cell is a TLC storing three bits of data, the first to eighth program operations may be performed. Similarly, as the number of bits stored by one memory cell increases, more program loops may be performed.

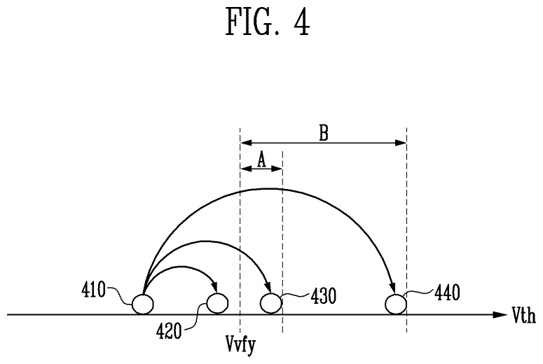

FIG. 4 is a diagram illustrating a threshold voltage distribution of memory cells which changes according to program pulses applied to the memory cells.

Referring to FIG. 4, a threshold voltage change of a memory cell to which a program pulse is applied is illustrated. In FIG. 4, the horizontal axis represents a threshold voltage, and threshold voltages of the memory cell to which the program pulse is applied may be shown as 420, 430, and 440.

By way of example, the memory cell originally has the threshold voltage 410. By way of example, the threshold voltage 420 represents the threshold voltage of the memory cell to which the second program pulse V2 of FIG. 2 is applied, the threshold voltage 430 represents the threshold voltage of the memory cell to which the first fixed program pulse VC1 of FIG. 3 is applied, and the threshold voltage 440 represents the threshold voltage of the memory cell to which the twelfth program pulse V12 of FIG. 2 is applied.

The threshold voltage 420 of the memory cell is lower than the verify voltage Vvfy. The third program pulse V3 needs to be applied to the memory cell having the threshold voltage 420 in the next program loop. Because the voltage level of the second program pulse V2 applied to the memory cell having the threshold voltage 420 does not sufficiently increase the threshold voltage of the memory cell having the threshold voltage 410, an additional program pulse needs to be applied. The application of the additional program pulse may increase the time required for program operation.

The threshold voltage 430 of the memory cell is higher than the verify voltage Vvfy. Based on the result of the verify operation included in the next program loop, the memory cell having the threshold voltage 430 may be included in the memory cells to which the program inhibition voltage is to be applied. It requires less time to perform the program operation when the first fixed program pulse VC1 is applied than when the second program pulse V2 is applied.

The threshold voltage 440 of the memory cell is higher than the verify voltage Vvfy. When the twelfth program pulse V12 is applied to the memory cell having the threshold voltage 410, the threshold voltage of the memory cell is higher than when the first fixed program pulse VC1 is applied. The difference between the threshold voltage 430 of the memory cell and the verify voltage Vvfy is A when the first fixed program pulse VC1 is applied, while the difference between the threshold voltage 440 of the memory cell and the verify voltage Vvfy is B when the twelfth program pulse V12 is applied, and thus it may be seen that B is greater than A. The larger the difference between the threshold voltage of the memory cell and the verify voltage Vvfy, the wider the threshold voltage distribution.

The threshold voltage distribution of the memory cells programmed in the manner illustrated in FIG. 2 may be wider than the threshold voltage distribution of the memory cells programmed in the manner illustrated in FIG. 3. The programming method illustrated in FIG. 3, corresponding to an embodiment of the present disclosure, may improve the threshold voltage distribution of the memory cells.

When performing the verify operation, a sensing error pertaining to a verify voltage or a verify current may occur. Due to the occurrence of the sensing error, a first verification error may occur in which the result of the verify operation is a verify-pass even when the threshold voltage of the memory cell is lower than the verify voltage Vvfy, or a second verification error may occur in which the result of the verify operation is a verify-fail even when the threshold voltage of the memory cell exceeds the verify voltage Vvfy.

According to an embodiment of the present disclosure, the verify operation on all memory cells coupled to the selected word line is performed anew before applying a fixed program pulse in each program loop, because the latch circuits storing the verification result of the previous program loop are reset. Because the verification results on all memory cells coupled to the selected word line are generated independently in all program loops, the threshold voltage distribution of the memory cells may be improved even when the first verification error or the second verification error occurs in one or more program loops.

As an example, the first verification error occurs, in which the result of the verify operation on the memory cell having the threshold voltage 420 is a verify-pass in the k-th program loop. When the program operation is performed according to the programming method described with reference to FIG. 2, the threshold voltage 420 of the memory cell remains lower than the verify voltage Vvfy until the program operation finishes. Because there is the memory cell having the threshold voltage 420 lower than the verify voltage Vvfy, the threshold voltage distribution of the program operation in which the first verification error occurs is wider than the threshold voltage distribution of the program operation in which the first verification error does not occur.

According to an embodiment of the present disclosure, even when the first verification error occurs in the k-th program loop, the threshold voltage 420 of the memory cell may be higher than the verify voltage Vvfy because the verify operation on the memory cell having the threshold voltage 420 in the (k+1)-th program loop is performed independently of that in the k-th program loop. Because the memory cell having the threshold voltage 420 lower than the verify voltage Vvfy does not exist, the threshold voltage distribution of the program operation performed according to an embodiment of the present disclosure may be narrower than the threshold voltage distribution of the program operation performed according to the programming method described with reference to FIG. 2.

As an example, the second verification error occurs, in which the result of the verify operation on the memory cell having the threshold voltage 430 or 440 is a verify-fail in the k-th program loop. When the program operation is performed according to the programming method described with reference to FIG. 2, a program pulse is applied to the memory cell having the threshold voltage 430 or 440 even when the threshold voltages 430 and 440 of the memory cell exceed the verify voltage Vvfy. As the threshold voltages 430 and 440 of the memory cell increase, the threshold voltage distribution of the program operation in which the second verification error occurs is wider than the threshold voltage distribution of the program operation in which the second verification error does not occur.

According to an embodiment of the present disclosure, even when the second verification error occurs in the k-th program loop, the threshold voltages 430 and 440 of the memory cell in the (k+1)-th program loop are not increased because the verify operation on the memory cell having the threshold voltage 430 or 440 in the (k+1)-th program loop is performed independently of that in the k-th program loop. Because the threshold voltages of the memory cells having the threshold voltages higher than the verify voltage Vvfy are not increased despite the occurrence of the second verification error, the threshold voltage distribution of the program operation performed according to an embodiment of the present disclosure may be narrower than the threshold voltage distribution of the program operation performed according to the programming method described with reference to FIG. 2.

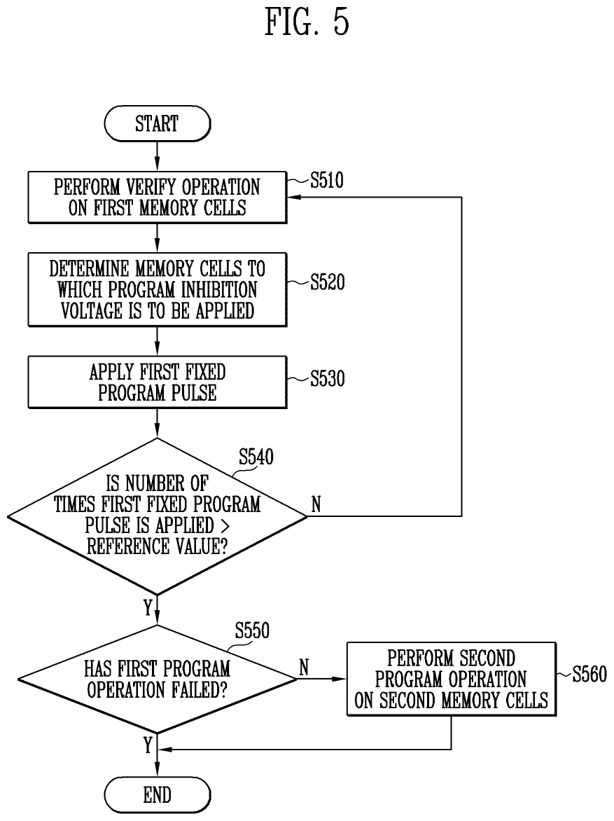

FIG. 5 is a flowchart illustrating a program operation according to an embodiment of the present disclosure.

Referring to FIG. 5, a memory device may perform a plurality of program loops including a program pulse apply operation for applying fixed program pulses having a constant voltage level to a plurality of memory cells coupled to a selected word line, and a verify operation for detecting whether a threshold voltage of the memory cell has reached a target level. The memory device may perform the verify operation on the memory cells before applying the fixed program pulse to the memory cells, and may determine, based on the result of performing the verify operation, memory cells to which a program inhibition voltage is applied when the fixed program pulse is applied. According to an embodiment of the present disclosure, a threshold voltage distribution of the memory cells may be narrower than a threshold voltage distribution of the memory cells according to a program operation of applying program pulses that are increased in a stepwise manner to the memory cells, thereby improving the threshold voltage distribution.

At operation S510, the memory device may perform the verify operation on first memory cells having a target threshold voltage of a first level. Specifically, a first verify operation included in an N-th program loop of the plurality of program loops may be performed. The memory cells that are subject to the first verify operation may include both verify-passed memory cells and verify-failed memory cells, which are the result of a second verify operation included in an (N−1)-th program loop.

At operation S520, control logic may determine the memory cells to which the program inhibition voltage is to be applied based on the result of the first verify operation and the target threshold voltages of the memory cells. The memory cells to which the program inhibition voltage is to be applied during a first program pulse apply operation included in the N-th program loop are memory cells having a target threshold voltage less than the first level and memory cells having a threshold voltage greater than or equal to the first level among the first memory cells.

In operation S530, the memory device may perform the first program pulse apply operation for applying a first fixed program pulse to the plurality of memory cells coupled to the selected word line. The control logic may control a peripheral circuit to apply the program inhibition voltage to the memory cells determined as the memory cells to which the program inhibition voltage is to be applied in operation S520 via bit lines when the first program pulse apply operation is performed.

In operation S540, the control logic may compare the number of times the first fixed program pulse is applied with a reference value after the first fixed program pulse is applied. When the number of times the first fixed program pulse is applied is less than the reference value, the operations may be repeated from operation S510 in an (N+1)-th program loop. When the number of times the first fixed program pulse is applied is greater than or equal to the reference value, operation S550 is performed.

At operation S550, the control logic may determine whether a first program operation on the first memory cells has failed. The control logic may determine whether the first program operation has failed based on the number of memory cells having a threshold voltage at or above the first level among the first memory cells. For example, when the number of memory cells having the threshold voltage at or above the first level is greater than or equal to a predetermined fail reference value, the control logic may determine the first program operation to be a pass. When the first program operation is determined to be the pass (“N” at operation S550), operation S560 may be performed.

At operation S560, the memory device may perform a second program operation on second memory cells having a target threshold voltage of a second level. The second program operation may be performed by performing a predetermined number of program loops, starting with the (N+1)-th program loop.

The description of each operation in FIG. 5 may correspond to the descriptions with reference to FIGS. 1, 3, and 4. In FIG. 5, an embodiment in which the first program operation and the second program operation are performed is illustrated, but additional program operations may be performed depending on the number of bits stored in one memory cell.

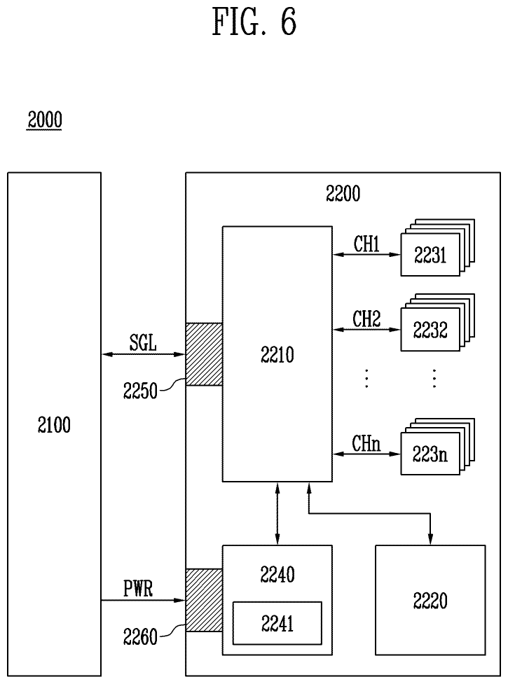

FIG. 6 is a diagram of a data storage system 2000 including a memory system according to an embodiment of the present disclosure.

Referring to FIG. 6, the data storage system 2000 may include a host device 2100 and a solid-state drive (SSD) 2200. The SSD 2200 may include a controller 2210, a buffer memory device 2220, non-volatile memories 2231 to 223n, a power supply 2240, a signal connector 2250, and a power connector 2260. The SSD 2200 may include the memory device 100 described with reference to FIGS. 1 to 5.

The buffer memory device 2220 may temporarily store data to be stored in the non-volatile memories 2231 to 223n. Additionally, the buffer memory device 2220 may temporarily store data read from the non-volatile memories 2231-223n. The data temporarily stored in the buffer memory device 2220 may be transferred to the host device 2100 or the non-volatile memories 2231 to 223n under control of the controller 2210.

The non-volatile memories 2231 to 223n may be used as storage media for the SSD 2200. Each of the non-volatile memories 2231 to 223n may be coupled to the controller 2210 via a plurality of channels CH1 to CHn. One channel may be coupled to one or more non-volatile memories. Non-volatile memories coupled to one channel may be coupled to the same signal bus and data bus.

The controller 2210 may control general operations of the SSD 2200. In an embodiment of the present disclosure, the controller 2210 may control the SSD 2200 to perform a program operation. The controller 2210 may control the SSD 2200 to perform a verify operation on memory cells before applying a fixed program pulse, and to apply a program inhibition voltage to memory cells, which are determined based on the result of the verify operation, when the fixed program pulse is applied to the memory cells. Accordingly, a threshold voltage distribution of the non-volatile memories 2231 to 223n may be improved.

The power supply 2240 may provide power PWR input via the power connector 2260 in the SSD 2200. The power supply 2240 may include an auxiliary power supply 2241. The auxiliary power supply 2241 may provide power to the SSD 2200 such that the SSD 2200 shuts down normally in the event of a sudden power off. The auxiliary power supply 2241 may include large capacitors that may charge the PWR.

The controller 2210 may transfer and receive signals SGL to and from the host device 2100 via the signal connector 2250. The signals SGL may include commands, addresses, data, and the like. The signal connector 2250 may be various types of connectors depending on an interface method of the host device 2100 and the SSD 2200.

The embodiments of the present disclosure are described by the claims below and the Detailed Description as set forth above. The embodiments of the present disclosure should be construed as including not only the scope of the claims but also all changes or modifications derived from the meanings, the scope, and equivalents of the claims. Furthermore, the embodiments may be combined to form additional embodiments.

According to some embodiments of the present disclosure, provided are a memory device and a method for performing a program operation that may reduce or mitigate deterioration in a threshold voltage distribution of memory cells caused by verification errors and the increase in program pulse magnitude, by performing a verify operation on memory cells before a program pulse apply operation, and determining memory cells to which a program inhibition voltage is to be applied according to a result of the verify operation.

What is claimed is:

1. A memory device, comprising:
a memory cell array including a plurality of memory cells coupled to a selected word line;
a peripheral circuit performing a program operation including a plurality of program loops each including:
a program pulse apply operation that applies fixed program pulses having a constant voltage level to the plurality of memory cells; and
a verify operation that detects whether a threshold voltage of a memory cell has reached a target level; and
control logic controlling the peripheral circuit to:
perform a first verify operation included in an N-th program loop among the plurality of program loops before performing a first program pulse apply operation included in the N-th program loop; and
apply a program inhibition voltage to memory cells determined, among the plurality of memory cells, based on a result of the first verify operation and target threshold voltages of the plurality of memory cells when the first program pulse apply operation is performed.

2. The memory device of claim 1, wherein the first program pulse apply operation is an operation that increases threshold voltages of first memory cells having a target threshold voltage of a first level among the plurality of memory cells by applying a first fixed program pulse,
wherein the first verify operation is an operation that verifies whether the threshold voltages of the first memory cells have reached the first level independently of a result of a second verify operation included in an (N−1)-th program loop, and
wherein the control logic:
determines first target memory cells having a threshold voltage lower than the first level among the first memory cells based on the result of the first verify operation; and
sets a voltage level of the first fixed program pulse based on the first level.

3. The memory device of claim 2, wherein the control logic controls the peripheral circuit to perform the first verify operation on the first memory cells including both verify-passed memory cells and verify-failed memory cells, which are the result of the second verify operation.

4. The memory device of claim 2, wherein the control logic controls the peripheral circuit to apply the program inhibition voltage to memory cells other than the first target memory cells among the plurality of memory cells.

5. The memory device of claim 4, wherein the control logic controls the peripheral circuit to perform the verify operation and the program pulse apply operation on the first memory cells in an (N+1)-th program loop in response to a number of times the first fixed program pulse is applied being less than a reference value.

6. The memory device of claim 4, wherein the control logic determines whether a first program operation on the first memory cells has failed based on a number of memory cells having a threshold voltage greater than or equal to the first level among the first memory cells in the N-th program loop, in response to a number of times the first fixed program pulse is applied being greater than or equal to a reference value.

7. The memory device of claim 6, wherein the control logic controls the peripheral circuit to perform the verify operation and the program pulse apply operation on second memory cells having a target threshold voltage of a second level among the plurality of memory cells in an (N+1)-th program loop, in response to the first program operation being determined to be a pass.

8. A method of operating a memory device, the method comprising:
performing a first verify operation included in an N-th program loop among a plurality of program loops each including a program pulse apply operation that applies fixed program pulses having a constant voltage level to a plurality of memory cells coupled to a selected word line and a verify operation that detects whether a threshold voltage of a memory cell has reached a target level;
determining memory cells to which a program inhibition voltage is to be applied among the plurality of memory cells based on a result of the first verify operation and target threshold voltages of the plurality of memory cells when a first program pulse apply operation included in the N-th program loop is performed; and
performing the first program pulse apply operation by applying the program inhibition voltage according to a result of the determination.

9. The method of claim 8, wherein performing the first program pulse apply operation includes:
determining first memory cells having a target threshold voltage of a first level among the plurality of memory cells;
resetting a result of a second verify operation included in an (N−1)-th program loop; and
verifying whether threshold voltages of the first memory cells have reached the first level, and
wherein the first program pulse apply operation is an operation that increases the threshold voltages of the first memory cells by applying a first fixed program pulse.

10. The method of claim 9, wherein determining the memory cells to which the program inhibition voltage is to be applied includes:
determining first target memory cells having a threshold voltage lower than the first level among the first memory cells based on the result of the first verify operation; and
determining, as the memory cells to which the program inhibition voltage is to be applied, memory cells other than the first target memory cells among the plurality of memory cells.

11. The method of claim 9, wherein in verifying whether the threshold voltages of the first memory cells have reached the first level, a verify operation on the first memory cells is performed without considering results of verify operations performed before the N-th program loop.

12. The method of claim 10, wherein performing the first program pulse apply operation includes:
setting a voltage level of the first fixed program pulse to be applied through the selected word line based on the first level; and
applying the first fixed program pulse to the plurality of memory cells and applying the program inhibition voltage to the memory cells other than the first target memory cells through bit lines coupled to the memory cells other than the first target memory cells when the first fixed program pulse is applied.

13. The method of claim 12, further comprising performing the verify operation and the program pulse apply operation on the first memory cells in an (N+1)-th program loop in response to a number of times the first fixed program pulse is applied being less than a reference value.

14. The method of claim 12, further comprising:
counting a number of memory cells having a threshold voltage greater than or equal to the first level among the first memory cells in response to a number of times the first fixed program pulse is applied being greater than or equal to a reference value; and
determining whether a first program operation on the first memory cells has failed based on the number of memory cells having the threshold voltage greater than or equal to the first level.

15. The method of claim 14, further comprising performing the verify operation and the program pulse apply operation on second memory cells having a target threshold voltage of a second level among the plurality of memory cells in an (N+1)-th program loop in response to the first program operation being determined to be a pass.

16. A memory device comprising:
a memory cell array including a plurality of memory cells coupled to a selected word line;
a peripheral circuit performing a program operation including:
a program pulse apply operation that applies fixed program pulses having a constant voltage level to the plurality of memory cells; and
a verify operation that detects whether a threshold voltage of a memory cell has reached a target level; and
control logic controlling the peripheral circuit to:
perform the verify operation before applying the fixed program pulses; and
apply a program inhibition voltage to memory cells determined, among the plurality of memory cells, based on a result of the verify operation and target threshold voltages of the plurality of memory cells.

17. The memory device of claim 16, wherein the control logic:
determines first memory cells having a target threshold voltage of a first level among the plurality of memory cells;
determines first target memory cells having a threshold voltage lower than the first level among the first memory cells based on the result of the verify operation; and
sets the voltage level of the fixed program pulses to a first voltage level based on the first level.

18. The memory device of claim 17, wherein the control logic controls the peripheral circuit to apply the program inhibition voltage to memory cells other than the first target memory cells among the plurality of memory cells, in response to the application of the fixed program pulses.

19. The memory device of claim 18, wherein the control logic controls the peripheral circuit to:
apply a first fixed program pulse having a voltage level of the first voltage level after performing the verify operation on the first memory cells; and
perform the verify operation and the program pulse apply operation on the first memory cells in response to a number of times the first fixed program pulse is applied being less than a reference value.

20. The memory device of claim 19, wherein the control logic determines whether the program operation on the first memory cells has failed based on a number of memory cells having a threshold voltage greater than or equal to the first level among the first memory cells, in response to the number of times the first fixed program pulse is applied being greater than or equal to the reference value.

21. The memory device of claim 20, wherein the control logic determines second memory cells having a target threshold voltage of a second level among the plurality of memory cells in response to the program operation on the first memory cells being determined to be a pass and controls the peripheral circuit to perform the verify operation on the second memory cells.

22. The memory device of claim 21, wherein the control logic determines second target memory cells having a threshold voltage lower than the second level among the second memory cells based on the result of the verify operation on the second memory cells and determines the voltage level of the fixed program pulses to a second voltage level based on the second level.

23. The memory device of claim 22, wherein the control logic controls the peripheral circuit to apply a second fixed program pulse having a voltage level of the second voltage level to the plurality of memory cells and to apply the program inhibition voltage to memory cells other than the second target memory cells among the plurality of memory cells.
